(19) United States
(12) Patent Application Publication
(10) Pub. No.: US 2025/0180647 A1
(43) Pub. Date: Jun. 5, 2025

(54) Monitoring Electrical Contactor Health

(71) Applicant: Caterpillar Inc., Peoria, IL (US)

(72) Inventors: Adam STUBBS, Lincolnshire (GB); Michael David SMITH, Cambridgeshire (GB); Craig COX, Sheffield (GB)

(73) Assignee: Caterpillar Inc., Peoria, IL (US)

(21) Appl. No.: 18/839,193

(22) PCT Filed: Jan. 23, 2023
(86) PCT No.: PCT/US2023/061057

§ 371 Date: Aug. 16, 2024

(30) Foreign Application Priority Data
Feb. 17, 2022 (GB) 2202124.0

(51) Int. Cl. G01R 31/333; H01H 1/00

(52) U.S. Cl. CPC G01R 31/3333; H01H 1/0015

(57) ABSTRACT

A method of monitoring contactor health for an electrical contactor of an electric apparatus, the electrical contactor being switchable in a switching event between an open state and a closed state or between a closed state and an open state. In response to a switching event instruction the method comprises determining a current value indicative of current flowing in the electrical contactor in the closed state at a time proximate to the switching event; attributing a percentage of a total contactor life estimate to the switching event based on the current value; determining an updated remaining percentage contactor life estimate by subtracting the percentage of total contactor life estimate from an initial remaining percentage contactor life estimate; and outputting the updated remaining percentage contactor life estimate.

### FIELD OF THE DISCLOSURE

The disclosure relates to the field of electric apparatus on a worksite.

### BACKGROUND

Electrical contactors are known to have a finite lifespan, and are usually capable of a finite number of actuations. The lifespan of the contactors is dependent on the current, and is generally shorter if the contactors are opened when the current draw is higher.

As an example, batteries of electric work vehicles contain at least one contactor that is used to break or complete the circuit, allowing the battery to be charged, discharged, or isolated. These contactors are electrically operated, and are typically high voltage contactors that comprise software-controlled switches. The contactors used in the batteries of electric work vehicles are often supplied with data that gives the expected lifetime of the contactor (in terms of the total number of actuations before failure occurs) if the contactor is opened each time at the same given current and voltage. In reality, a contactor in a battery will be opened at a variety of currents over its lifetime, and so the lifetime will deviate from the data supplied.

Contactors with a finite lifetime that depends on the current and voltage may also be found in other electric apparatus on a worksite, such as other electric work machines, chargers, electric generator sets, or other apparatus.

### SUMMARY OF THE DISCLOSURE

Against this background, there is provided a method of monitoring contactor health for an electrical contactor of an electric apparatus, the electrical contactor being switchable in a switching event between an open state and a closed state or between a closed state and an open state. In response to a switching event instruction the method comprises determining a current value indicative of current flowing in the electrical contactor in the closed state at a time proximate to the switching event. The method further comprises attributing a percentage of a total contactor life estimate to the switching event based on the current value, wherein the total contactor life estimate is an estimate of the total life of the contactor. The method further comprises determining an updated remaining percentage contactor life estimate by subtracting the percentage of total contactor life estimate from an initial remaining percentage contactor life estimate, wherein the updated remaining percentage contactor life estimate comprises an estimate of the life of the contactor following the switching event and the initial remaining percentage contactor life estimate comprises an estimate of the life of the contactor prior to the switching event. The method further comprises outputting the updated remaining percentage contactor life estimate.

There is also provided a device for monitoring contactor health for an electrical contactor of an electric apparatus, the electrical contactor being switchable in a switching event between an open state and a closed state or between a closed state and an open state. In response to a switching event instruction the device is configured to determine a current value indicative of current flowing in the electrical contactor in the closed state at a time proximate to the switching event. The device is further configured to attribute a percentage of a total contactor life estimate to the switching event based on the current value, wherein the total contactor life estimate is an estimate of the total life of the contactor. The device is further configured to determine an updated remaining percentage contactor life estimate by subtracting the percentage of total contactor life estimate from an initial remaining percentage contactor life estimate, wherein the updated remaining percentage contactor life estimate comprises an estimate of the life of the contactor following the switching event and the initial remaining percentage contactor life estimate comprises an estimate of the life of the contactor prior to the switching event. The device is further configured to output the updated remaining percentage contactor life estimate.

In this way, the remaining life of the contactor can be monitored by using a current value at which the switching event occurred to attribute a percentage of total contactor life estimate that is estimated to have been used during the switching event. As the lifetime of a contactor varies depending on current, this allows an accurate prediction of the remaining lifetime of a contactor even when the current may vary between switching events.

### BRIEF DESCRIPTION OF THE DRAWINGS

A specific embodiment of the disclosure will now be described, by way of example only, with reference to the accompanying drawings in which:

FIG. 1 shows a flow diagram illustrating a method of monitoring contactor health in accordance with an embodiment of the present disclosure.

FIG. 2 shows a flow diagram illustrating a method of monitoring contactor health in accordance with an embodiment of the present disclosure.

FIG. 3 shows a schematic histogram of number of switching events against current, with two distributions (shown in FIGS. 3A and 3B).

FIG. 4 shows a schematic graph of the relationship between a percentage of the total contactor life by which the contactor life has been reduced during the switching event and a current at which the switching event occurs.

FIG. 5 shows a schematic graph of the relationship between total lifetime of a contactor and a current at which the switching events occur.

### DETAILED DESCRIPTION

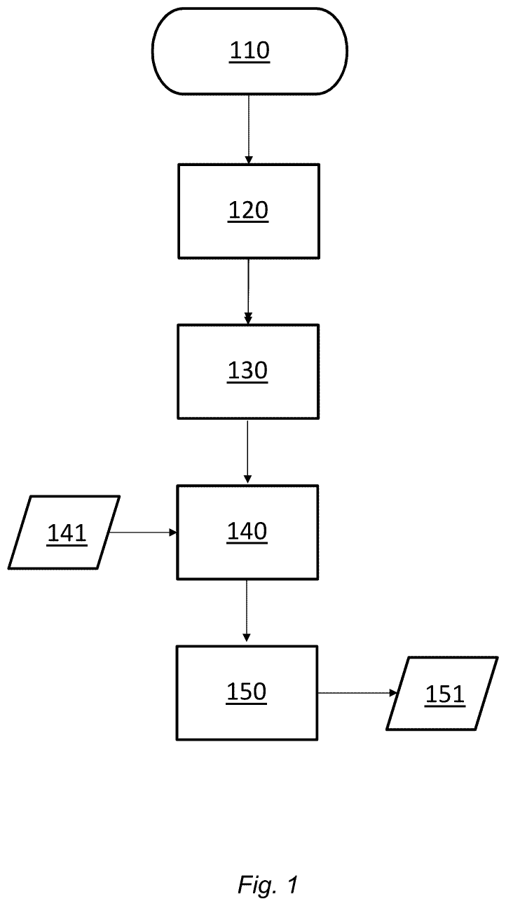

An electrical contactor of an electric apparatus is switchable in a switching event between an open state and a closed state or between a closed state and an open state. With reference to FIG. 1, in response to a switching event instruction 110, a method of monitoring contactor health comprises determining (at step 120) a current value indicative of current flowing in the electrical contactor in the closed state at a time proximate to the switching event. The current value may be indicative of current flowing in the electrical contactor before the contactor switches from the closed state to the open state, or after the contactor switches from the open state to the closed state. The current value may comprise the maximum current in a period of time including the switching event instruction. The maximum current may be the actual peak of the current in a period of time, may be close to the peak (for example, the peak may fall between measured current samples, in which case the highest measured current may be chosen as the maximum current).

At step 130, the method further comprises attributing a percentage of a total contactor life estimate to the switching event based on the current value, wherein the total contactor life estimate is an estimate of the total life of the contactor. The percentage of a total contactor life estimate is the estimate of the percentage of the total contactor life by which the contactor life has been reduced during the switching event. The percentage of total contactor life estimate may be further based on a voltage value indicative of the system voltage or a voltage across the electrical contactor in the open state at a time proximate to the switching event. The voltage value may comprise a nominal voltage value or a measured voltage value. In an embodiment, the voltage value may be known to be the same for every switching event, in which case the percentage of total contactor life estimate may be based only on the current value. At step 140, an updated remaining percentage contactor life estimate 151 is determined by subtracting the percentage of total contactor life estimate from an initial remaining percentage contactor life estimate 141. The updated remaining percentage contactor life estimate 151 comprises an estimate of the life of the contactor following the switching event. The initial remaining percentage contactor life estimate 141 comprises an estimate of the life of the contactor prior to the switching event. The method further comprises outputting the updated remaining percentage contactor life estimate 151 at step 150.

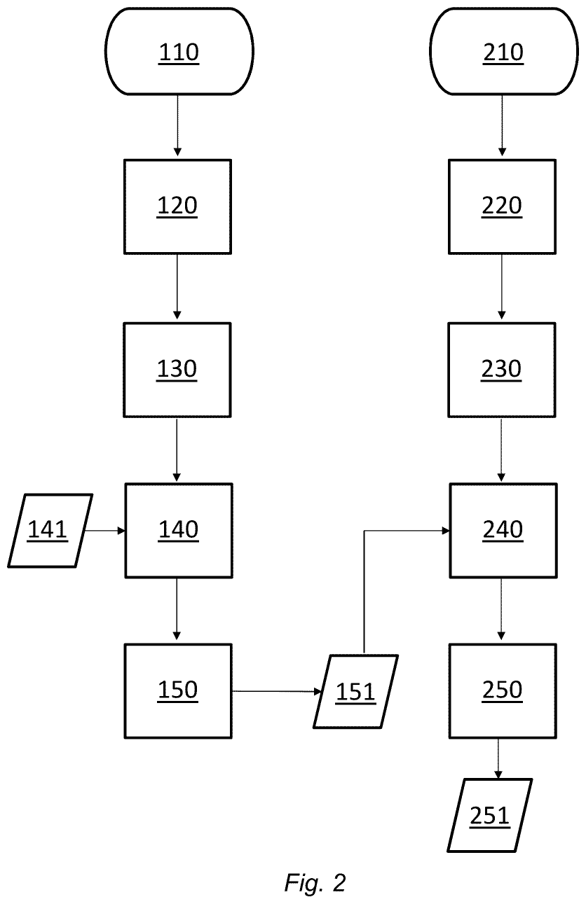

The updated remaining percentage contactor life 151 estimate may then be used as the initial remaining percentage contactor life estimate 141 for the next switching event. With reference to FIG. 2, a first switching instruction 110 is made for a first switching event. At step 120, a first current value indicative of current flowing in the electrical contactor in the closed state at a time proximate to the first switching event. At step 130, the method further comprises attributing a first percentage of a total contactor life estimate to the first switching event based on the first current value, wherein the total contactor life estimate is an estimate of the total life of the contactor. At step 140, a first updated remaining percentage contactor life estimate 151 is determined by subtracting the first percentage of total contactor life estimate from an initial remaining percentage contactor life estimate 141. The first updated remaining percentage contactor life estimate 151 is outputted at step 150. A second switching instruction 210 is then made at a later time for the second switching event (the next switching event after the first switching event). At step 220, a second current value indicative of current flowing in the electrical contactor in the closed state at a time proximate to the second switching event. At step 230, the method further comprises attributing a second percentage of a total contactor life estimate to the second switching event based on the second current value, wherein the total contactor life estimate is an estimate of the total life of the contactor. At step 240, a second updated remaining percentage contactor life estimate 251 is determined by subtracting the second percentage of total contactor life estimate from the first updated remaining percentage contactor life estimate 151 (used as the initial remaining percentage contactor life). The second updated remaining percentage contactor life estimate 251 is outputted at step 250. The second updated remaining percentage contactor life estimate 251 may be used as the initial remaining percentage contactor life for the method in response to the next switching event, and so on.

This may be explained further via equations. The updated remaining percentage contactor life following a switching event can be calculated from the following equation:

$${L}_{R e} = {L}_{R ( e - 1 )} - Δ {L}_{R e}$$

Where:
L_{Re} is the updated remaining percentage contactor life estimate after the switching event e (with reference to the example shown in FIG. 2, this is the second updated remaining percentage contactor life estimate after the second switching event e),
L_{R(e-1)} is the initial remaining percentage contactor life estimate prior to the switching event, and corresponds to the remaining percentage contactor life estimate after the previous event e−1 (with reference to the example shown in FIG. 2, this is the first updated remaining percentage contactor life estimate after the second switching event e−1),
ΔL_{Re} is the percentage of a total contactor life estimate, i.e. the estimate of the percentage reduction of contactor life due to the switching event e (with reference to the example shown in FIG. 2, this is the second percentage of a total contactor life estimate for the second switching event e)

The percentage of a total contactor life estimate, ΔL_{Re}, can be calculated from the maximum number of cycles the contactor is expected to perform at the current value (for example, as specified by the contactor manufacturer) by the following equation:

ΔL_{Re}=100/N_{cycles}

N_{cycles} is the expected number of cycles for a particular contactor type at the current value. N_{cycles} is in general a function of both the maximum current value, I_{MAX}, and the system voltage, V, i.e., N_{cycles}=f(V, I_{MAX}). I_{MAX} may determined by taking the maximum current over a period of time including the switching event instruction.

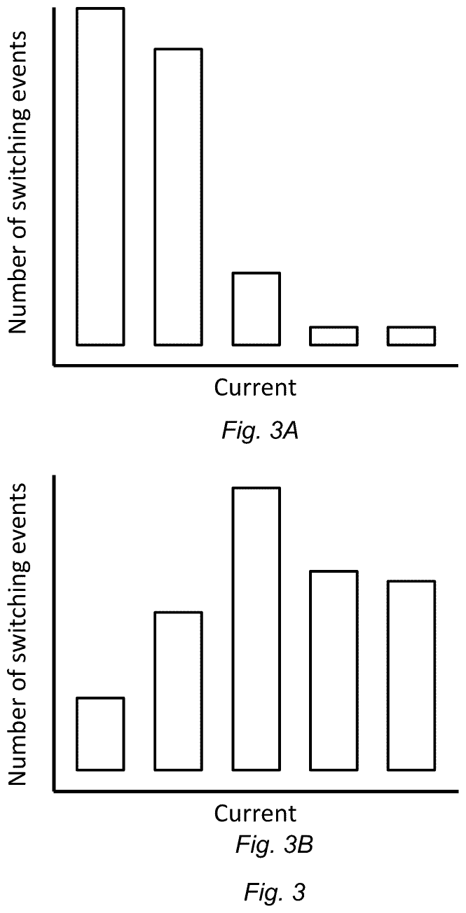

The method may further comprise recording the current value (wherein the current value may comprise the maximum current in a period of time including the switching event instruction). The switching current may be recorded by incrementing one of a plurality of bins. Each bin may correspond to a current range, such that the bin that is incremented corresponds to a current range that includes the current value. The recorded current value may be communicated to a controller. The bins may be communicated to a controller or an operator in the form of a histogram, as numerical values, or by other means. The bins may correspond to current ranges above a threshold current value. The total number of switching events recorded in each bin may be summed. The total number of switching events recorded in all bins may be summed. In a schematic shown in FIG. 3, two examples of bin distributions are shown for the same sets of bins corresponding to the same current ranges. Number of switching events is plotted against current. FIG. 3A shows a distribution in which most switching events occur in the lower two bins. FIG. 3B shows a distribution in which more switching events occur at higher currents than the distribution in FIG. 3A. This may be used in a predictive setting, by using the currents at which a contactor has previously been switched to predict the currents at which it may be switched in future, and therefore predict the number of switching events that the remaining percentage contactor life estimate might correspond to. For example, if it is known that a particular contactor is usually switched at a lower current (as in FIG. 3A), the remaining percentage contactor life estimate might correspond to a higher number of switching events than if the contactor is usually switched at a higher current (as in FIG. 3B). The number of bins and distributions shown are purely demonstrative, and may vary considerably. The bins are shown with equal widths for simplicity. The current ranges for each bin may be equal in size, or different in size.

Recording the current value of each switching event in this way may allow an operator or controller to analyse how the contactors have been used. It may then be possible to use the past data to provide context to the remaining percentage contactor life estimate. In an embodiment, a user may be notified of switching data based on recorded current data from previous switching events. For example, based on the previous current values at which the switching events have occurred it may be possible to convert the remaining percentage contactor life estimate to a predicted number of remaining switching events. In an example, the predicted number of remaining switching events may be based on an average current value recorded, which may be used to attribute a predicted number of remaining switching events based on a lookup table. In another example, the predicted number of remaining switching events may be based on the number of switching events recorded and the initial remaining percentage contactor life estimate (for example, by calculating the average percentage contactor life used for each switching event). The recorded current values may be used in other ways to predict the number of remaining switching events.

In an embodiment, a user may be notified in the event that the predicted number of remaining switching events falls below a threshold value. For example, the user may be notified via a warning light on the electric apparatus, a message displayed on a user interface (wherein the user interface may comprise a display on the electric apparatus, a portable device, or other display), an electronic message, or other means. In another embodiment, the predicted number of remaining switching events may be converted to a predicted duration of use of the electric apparatus before the contactor needs replacing. For example, the average time increment between each switching event may be known and used to convert the predicted number of remaining switching events to a time period. In an embodiment, the method may comprise recording the date and time of a switching event. In an embodiment, a user may be notified in the event that the predicted duration of use falls below a threshold value. For example, the user may be notified via a warning light on the electric apparatus, a message displayed on a user interface (wherein the user interface may comprise a display on the electric apparatus, a portable device, or other display), an electronic message, or other means.

The step of outputting the remaining percentage contactor life estimate may comprise at least one of communicating the updated remaining percentage contactor life estimate to a controller and notifying a user of the remaining percentage contactor life estimate. Notifying a user may comprise displaying the remaining percentage contactor life estimate on a user interface (for example on the electric apparatus or via a portable device).

The current value may comprise the maximum current in a period of time including the switching event instruction. In an embodiment, the current value may comprise the maximum current from a plurality of current samples measured before and after and at the point of the switching event instruction, or before and after the point of the switching event instruction. For example, the current value may comprise the maximum current from a first current measurement before the point of the switching event instruction, a second current measurement at the point of the switching event instruction and a third current measurement after the point of the switching event instruction. The current value may comprise the maximum of a current vector recorded across a defined time period that includes the switching event. The current vector may comprise more than two current values. For example, the current vector may comprise between two and ten current values. in an example, the defined time period may be of the order of 10 ms, but it may be shorter or longer. In another embodiment, a sensor may be used to detect the maximum current during the defined time period (such that the actual maximum current during the defined time period is detected, rather than choosing the maximum current value from a plurality of current samples). In another embodiment, the maximum current may be measured at a pre-determined time relative to the switching event instruction, for example in an event that the time of the maximum current is predicted based on previous measurements.

The percentage of a total contactor life estimate attributed to the switching event may be further based on a voltage value. The voltage value, as discussed earlier, may be indicative of the system voltage or a voltage across the electrical contactor in the open state at a time proximate to the switching event. The voltage value may a nominal voltage (for example if it is known that the electrical contactor is switched at a given voltage) or may be measured. In an event that the voltage value is measured, it may comprise the voltage at the point at which the current value is measured. For example, the current value may comprise the maximum current in a period of time including the switching event instruction and the voltage value may comprise the voltage measured at the point of the maximum current.

The step of attributing a percentage of a total contactor life estimate to the switching event based on the current value may be achieved by comparing the current value to a pre-determined list of calibration current values corresponding to known percentages of total contactor life. The step of attributing a percentage of a total contactor life estimate to the switching event based on the current value and the voltage value may be achieved by comparing the current value and voltage value to a pre-determined list of calibration current values and calibration voltage values corresponding to known percentages of total contactor life.

In an embodiment, the percentage attributed may be the percentage from the list that corresponds to a calibration current value closest to the current value at a time proximate to the switching event. In another embodiment the percentage attributed may be determined from the two percentages from the list that correspond to the two calibration current values closest to the current value at a time proximate to the switching event. For example, in the event that the current value is between calibration current values of the pre-determined list, the updated remaining percentage contactor life estimate may be determined by linear interpolation (the linear interpolation may be carried out on a log scale). This may be based on an assumption of linearity (on a log scale) between the percentage of total contactor life at the closest current value above the switching current and the percentage of total contactor life at the closest current value below the switching current.

The pre-determined list of calibration current values corresponding to known percentages of total contactor life may correspond to the voltage at which the switching event occurs. A plurality of pre-determined lists may each correspond to a different voltage. Similarly, the total contactor life as a function of current may correspond to the voltage at which the switching event occurs. The pre-determined list of calibration current values corresponding to known percentages of total contactor life (or the total contactor life as a function of current) may be for single switching events (between an open state and a closed state or between a closed state and an open state), or for double switching events (between an open state and a closed state and between a closed state and an open state).

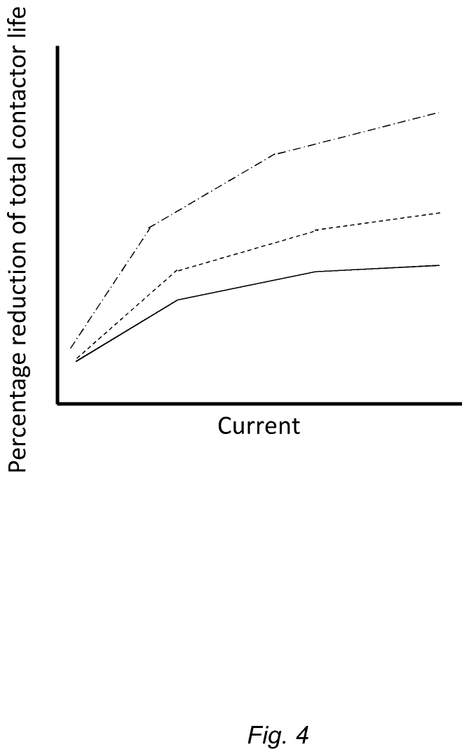

With reference to FIG. 4, a schematic graph is shown to illustrate a possible relationship between percentage of total contactor life (used in a switching event) against current, for three voltages. The solid line is at lowest voltage, the dash-dot line is at the highest voltage and the dashed line is at a voltage between the lowest voltage and the highest voltage. The percentage of total contactor life used in a switching event increases with current. For a given current, the percentage of total contactor life used in a switching event is larger the higher the voltage. In the example shown, linearity is assumed between data points (this may occur on a log scale). There may be more data points than shown, and linearity may or may not be assumed between data points.

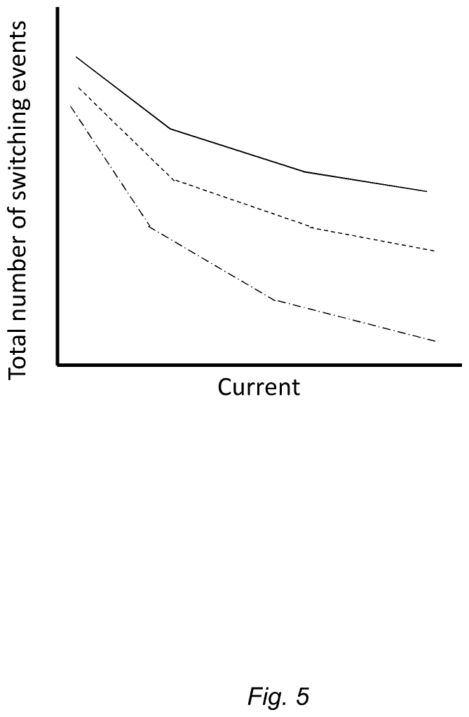

With reference to FIG. 5, a schematic graph is shown to illustrate a possible relationship between total lifetime of the contactor (as total number of switching events) against current, for three voltages. Each point on the graph indicates the expected total number of switching events at a given current and voltage that the contactor can undergo in a lifetime, wherein each point on the graph assumes that each switching event occurs at the same given current and voltage. The solid line is at lowest voltage, the dash-dot line is at the highest voltage and the dashed line is at a voltage between the lowest voltage and the highest voltage. The lifetime decreases with current. For a given current, the lifetime is shorter the higher the voltage. In the example shown, linearity is assumed between data points (this may occur on a log scale). There may be more data points than shown, and linearity may or may not be assumed between data points.

The pre-determined list of calibration current values corresponding to known percentages of total contactor life may be determined based on a pre-determined list of calibration current values corresponding to known total contactor life as a total number of switching events (wherein percentage of total contactor life=100/total number of switching events).

In another embodiment, the pre-determined list of current values corresponding to known percentages of total contactor life may be determined from total contactor life as a function of current and voltage. In another embodiment, total contactor life as a function of current may be known and used for the step of attributing a percentage of a total contactor life estimate to the switching event based on the current value.

In another embodiment of the present disclosure, there is a device for monitoring contactor health. An electrical contactor of an electric apparatus is switchable in a switching event between an open state and a closed state or between a closed state and an open state. In response to a switching event instruction the device is configured to. Determine a current value indicative of current flowing in the electrical contactor in the closed state at a time proximate to the switching event. The device is further configured to attribute a percentage of a total contactor life estimate to the switching event based on the current value, wherein the total contactor life estimate is an estimate of the total life of the contactor. The device is further configured to determine an updated remaining percentage contactor life estimate by subtracting the percentage of total contactor life estimate from an initial remaining percentage contactor life estimate. The updated remaining percentage contactor life estimate comprises an estimate of the life of the contactor following the switching event, and the initial remaining percentage contactor life estimate comprises an estimate of the life of the contactor prior to the switching event. The device is further configured to output the remaining percentage contactor life estimate.

The device may be further configured to carry out any of the methods set out elsewhere in the description.

1. A method of monitoring contactor health for an electrical contactor of an electric apparatus, the electrical contactor being switchable in a switching event between an open state and a closed state or between a closed state and an open state, wherein in response to a switching event instruction the method comprises:
determining a current value indicative of current flowing in the electrical contactor in the closed state at a time proximate to the switching event;
attributing a percentage of a total contactor life estimate to the switching event based on the current value, wherein the total contactor life estimate is an estimate of the total life of the contactor;
determining an updated remaining percentage contactor life estimate by subtracting the percentage of total contactor life estimate from an initial remaining percentage contactor life estimate, wherein the updated remaining percentage contactor life estimate comprises an estimate of the life of the contactor following the switching event and the initial remaining percentage contactor life estimate comprises an estimate of the life of the contactor prior to the switching event; and
outputting the updated remaining percentage contactor life estimate.

2. The method of claim 1, wherein the current value comprises the maximum current in a period of time including the switching event instruction.

3. The method of claim 2, wherein the current value comprises the maximum current from a plurality of current samples measured either:
before, after and at the point of the switching event instruction; or
before and after the point of the switching event instruction.

4. The method of claim 2, wherein the maximum current is measured at a pre-determined time relative to the switching event instruction.

5. The method of claim 1, further comprising recording the current value.

6. The method of claim 5, wherein the current value is recorded by incrementing one of a plurality of bins, each bin corresponding to a current range, wherein the bin that is incremented corresponds to a current range that includes the current value.

7. The method of claim 5, further comprising at least one of:
communicating the recorded current value to a controller; and
notifying a user of switching data based on recorded current data from previous switching events.

8. The method of claim 5, further comprising using a distribution of the plurality of bins to predict the remaining life of the contactor, wherein the remaining life comprises at least one of:
an estimated remaining number of switching events; and
an estimated remaining duration of use of the electric apparatus before the end of the contactor life.

9. The method of claim 8, further comprising notifying a user in the event that the contactor life falls below a threshold remaining number of switching events or a threshold remaining duration of use.

10. The method of claim 8, wherein outputting the remaining percentage contactor life estimate comprises at least one of:
communicating the updated remaining percentage contactor life estimate to a controller; and
notifying a user of the remaining percentage contactor life estimate.

11. The method of claim 8, wherein the attributing a percentage of a total contactor life estimate to the switching event is further based on a voltage value, wherein the voltage value is indicative of a system voltage or a voltage across the electrical contactor in the open state at a time proximate to the switching event.

12. The method of claim 8, wherein the attributing a percentage of a total contactor life estimate to the switching event based on the current value is achieved by comparing the current value to a pre-determined list of current values corresponding to known percentages of total contactor life.

13. The method of claim 8, wherein in the event that the current value is between current values of the pre-determined list of current values, the updated remaining percentage contactor life estimate is determined by assuming linearity on a log scale between the percentage of total contactor life at the closest current value above the switching current and the percentage of total contactor life at the closest current value below the switching current.

14. The method of claim 8, wherein the pre-determined list of current values corresponding to known percentages of total contactor life is determined from total contactor life as a function of at least one of current and voltage.

15. A device for monitoring contactor health for an electrical contactor of an electric apparatus, the electrical contactor being switchable in a switching event between an open state and a closed state or between a closed state and an open state, wherein in response to a switching event instruction the device is configured to:
determine a current value indicative of current flowing in the electrical contactor in the closed state at a time proximate to the switching event;
attribute a percentage of a total contactor life estimate to the switching event based on the current value, wherein the total contactor life estimate is an estimate of the total life of the contactor;
determine an updated remaining percentage contactor life estimate by subtracting the percentage of total contactor life estimate from an initial remaining percentage contactor life estimate, wherein the updated remaining percentage contactor life estimate comprises an estimate of the life of the contactor following the switching event and the initial remaining percentage contactor life estimate comprises an estimate of the life of the contactor prior to the switching event; and
output the updated remaining percentage contactor life estimate.
